(19) United States
(12) Patent Application Publication
(10) Pub. No.: US 2025/0291018 A1
(43) Pub. Date: Sep. 18, 2025

(54) MULTI-SHOT MAGNETIC RESONANCE (MR) IMAGE RECONSTRUCTION

(71) Applicant: Hyperfine, Inc., Guilford, CT (US)

(72) Inventors: Tianrui LUO, Guilford, CT (US); Laura SACOLICK, Guilford, CT (US); Melissa HASKELL, Guilford, CT (US)

(21) Appl. No.: 19/222,958

(22) Filed: May 29, 2025

Related U.S. Application Data
(63) Continuation of application No. PCT/US2022/051455, filed on Nov. 30, 2022.

(51) Int. Cl. G01R 33/567; G01R 33/563; G01R 33/565

(52) U.S. Cl. CPC G01R 33/5676; G01R 33/56341; G01R 33/56509

(57) ABSTRACT

Systems and methods for estimating navigator maps for multi-shot phase-navigated image reconstruction are provided. The techniques described herein include acquiring a reference image of a subject, calculating, for a multi-shot MR image of the subject, a navigator map using the reference image, and reconstructing the multi-shot MR image by applying the navigator maps to segments of the multi-shot MR image. The MR image and the reference image may be, for example, a T1-weighted image, a T2-weighted image, a fluid-attenuated inversion recovery (FLAIR) image, DWI image, a water separated image, fat separated image, a fat suppressed image, a phase contrasted image, or a blood contrasted image. The reference image may be a different type, and/or acquired from the same or a different sequence than the MR image. The navigator maps may correct for shot-varying motion-induced phase differences in the multi-shot MR image.

### CROSS-REFERENCE TO RELATED APPLICATION

This application claims the benefit under 35 U.S.C. § 120 as a continuation of PCT Patent Application No. PCT/US2022/051455, filed on Nov. 30, 2022, the entire contents of which are incorporated herein by reference.

### FIELD

This disclosure relates generally to multi-shot magnetic resonance (MR) image reconstruction, to regularized convolution kernel estimation-based phase-navigated multi-shot MR image reconstruction, and to motion-correction in multi-shot images using a reference image.

### BACKGROUND

Magnet resonance imaging (MRI) systems may be utilized to generate images of the inside of the human body. MRI systems may be used to detect magnetic resonance (MR) signals in response to applied electromagnetic fields. MRI techniques may include diffusion weighted imaging (DWI), via which water diffusion is used to investigate the white matter activity in the human brain. DWI processing techniques may be utilized with the goal of addressing resolution issues for images produced using DWI. Multi-shot images complicate image reconstruction because changing patient motion across different shots causes phase inconsistency.

### SUMMARY

At least one aspect of the present disclosure is directed to a method for compensating for motion in multi-shot MR images, the image processing method comprising estimating phase variations among a plurality of shots of acquired MR imaging data by (a) acquiring a reference image of a subject; (b) calculating, for each shot of the plurality of shots, a navigator map using (i) first data of the shot, and (ii) second data of the reference image; and (c) reconstructing a multi-shot MR image of the subject by applying the navigator maps of (b) to the plurality of shots of acquired MR imaging data.

In some implementations, the plurality of shots of acquired MR imaging data is acquired separately from the reference image. In some implementations, (b) comprises minimizing a regularized difference between (i) a Fourier transform of the second data of the reference image convolved with the navigator map, and (ii) a respective shot of the plurality of shots. The Fourier transform may be a partial Fourier transform. In some implementations, the regularized difference is a difference on a limited region of the k-space per shot. In some implementations, the method includes regularizing the phase variations to allow for calculation of navigator maps from undersampled data. In some implementations, regularizing the phase variations comprises using a geometric shape regularizer, a null space regularizer, or a combination of the geometric shape regularizer and the null space regularizer.

In some implementations, the reference image is a diffusion-weight image (DWI) with a zero b-value, and each shot of the plurality of shots is a respective DWI image with a b-value greater than zero. In some implementations, the multi-shot MR image is a T1-weighted image, a T2-weighted image, a fluid-attenuated inversion recovery (FLAIR) image, or a DWI image. In some implementations, the navigator maps are used to select shots in the plurality of shots that should be rejected and reacquired.

At least one other aspect of the present disclosure is directed to a method for generating motion phase maps for multi-shot MR image reconstruction. The method may include generating a transformation of a reference image of a subject. The reference image may correspond to a set of signals captured from a magnetic resonance (MR) scan of the subject. The method may include generating an estimated convolutional kernel according to the set of signals and the transformation of the reference image. The method may include generating a motion phase map for the set of signals according to a transform of the estimated convolutional kernel.

In some implementations, the reference image of the subject is captured using a first imaging process and the set of signals are captured using a second imaging process. In some implementations, the set of signals correspond to a T1-weighted image, a T2-weighted image, a fluid-attenuated inversion recovery (FLAIR) image, a DWI image, a water separated image, a fat separated image, a fat suppressed image, a phase contrasted image, or a blood contrasted image. In some implementations, the reference image comprises a T1-weighted image, a T2-weighted image, a FLAIR image, a DWI image, a water separated image, a fat separated image, a fat suppressed image, a phase contrasted image, or a blood contrasted image. In some implementations, the method includes generating a navigator map comprising the motion phase map and a magnitude map according to the transformation of the estimated convolutional kernel.

In some implementations, the method includes detecting motion in DWI data exceeding a defined level, according to the set of signals and the navigator map. In some implementations, generating the estimated convolutional kernel comprises executing a regularizer according to a set of regularization terms. In some implementations, the method includes generating one or more reconstructed multi-shot MR images according to the motion phase map.

At least one other aspect of the present disclosure is directed to a system for generating motion phase maps for multi-shot magnetic resonance image reconstruction. The system may include one or more processors coupled to a non-transitory memory. The system may generate a transformation of a reference image of a subject. The reference image may correspond to a set of signals captured from a magnetic resonance (MR) scan of the subject. The system may generate an estimated convolutional kernel according to the set of signals and the transformation of the reference image. The system may generate a motion phase map according to a transform of the estimated convolutional kernel.

At least one other aspect of the present disclosure is directed to an image processing method for compensating for motion in MR images. The image processing method may include estimating phase variations among segments of acquired imaging data by: (a) acquiring a reference image of a subject; (b) calculating, for a multi-shot MR image of the subject, a navigator map using the reference image; and (c) reconstructing the multi-shot MR image by applying the navigator maps of (b) to segments of the multi-shot MR image.

Yet another aspect of the present disclosure is directed to a method of MRI reconstruction with multi-shot MRI pulse sequences. The method includes (a) obtaining a reference image; (b) acquiring a multi-shot interleaved MR image that has shot-variant and shot-invariant phase modulations; (c) estimating complex-valued shot-specific navigator maps that correspond to the element-wise ratio map between (i) the multi-shot interleaved MR image with shot-varying phase modulations, and (ii) the reference image; (d) using the navigator maps to select shots that should be rejected or reacquired; (e) applying the navigator maps to correct motion or system induced image phase for the multi-shot interleaved MR image; and (f) performing navigated image reconstruction of k-space data from all shots of the multi-shot interleaved MR image using the estimated navigator maps.

In some implementations, the reference image comprises an image with different contrast than the multi-shot interleaved MR image, a combination of reference images, or an image scanned for calibration purposes. In some implementations, the reference image is well-aligned with and overlaps with the multi-shot interleaved MR image. In some implementations, the acquisition has a same coil sensitivity profile as the reference image. In some implementations, a shot-invariant phase difference map is estimated between the reference and the multi-shot interleaved DWI and applied by: (i) estimating the shot-invariant image phase difference map of the multi-shot interleaved MR image of (b); and (ii) applying the shot-invariant phase difference map to either the reference image or the multi-shot interleaved MR image such that both data have the same shot-invariant phase.

In some implementations, the shot-invariant phase difference map is obtained via non-navigated reconstruction of k-space data from partial or all shots of the multi-shot imaging. In some implementations, (c) comprises performing an image-domain regularized minimization technique that generates the navigator maps. In some implementations, the regularized minimization techniques are performed using k-space data or using data in a hybrid image-frequency domain. In some implementations, the hybrid image-frequency domain is defined as any intermittent domain after incomplete multi-dimensional Fourier transform.

These and other aspects and implementations are discussed in detail below. The foregoing information and the following detailed description include illustrative examples of various aspects and implementations, and provide an overview or framework for understanding the nature and character of the claimed aspects and implementations. The drawings provide illustration and a further understanding of the various aspects and implementations, and are incorporated in and constitute a part of this specification. Aspects may be combined and it will be readily appreciated that features described in the context of one aspect of the present disclosure may be combined with other aspects. Aspects may be implemented in any convenient form. In a non-limiting example, by appropriate computer programs, which may be carried on appropriate carrier media (computer readable media), which may be tangible carrier media (e.g. disks) or intangible carrier media (e.g. communications signals). Aspects may also be implemented using suitable apparatus, which may take the form of programmable computers running computer programs arranged to implement the aspect. As used in the specification and in the claims, the singular form of “a,” “an,” and “the” include plural referents unless the context clearly dictates otherwise.

### BRIEF DESCRIPTION OF THE DRAWINGS

The accompanying drawings are not intended to be drawn to scale. Like reference numbers and designations in the various drawings indicate like elements. For purposes of clarity, not every component may be labeled in every drawing. In the drawings:

FIG. 1A illustrates example components of a magnetic resonance imaging system, in accordance with one or more implementations;

FIG. 1B illustrates an example system for estimating navigator maps for DWI image reconstruction, in accordance with one or more implementations;

FIG. 2 depicts an example dataflow diagram of an example process for estimating navigator maps for multi-shot magnetic resonance (MR) image reconstruction, in accordance with one or more implementations;

FIG. 3 depicts an example dataflow diagram of another process for estimating navigator maps for multi-shot MR image reconstruction, in accordance with one or more implementations;

FIG. 4 depicts a flowchart of an example method of estimating a navigator map for multi-shot MR data using a reference image and performing multi-shot MR image reconstruction using the navigator map, in accordance with one or more implementations;

FIG. 5 shows an example reference image of a patient, in accordance with one or more implementations;

FIG. 6 shows an example DWI image of a patient without motion correction, in accordance with one or more implementations;

FIG. 7 shows an example DWI image of a patient on which image correction has been performed, in accordance with one or more implementations; and

FIG. 8 is a block diagram of an example computing system suitable for use in the various arrangements described herein, in accordance with one or more example implementations.

### DETAILED DESCRIPTION

Below are detailed descriptions of various concepts related to and implementations of techniques, approaches, methods, apparatuses, and systems for phase-navigated multi-shot MR image reconstruction using estimated convolution kernels. The various concepts introduced above and discussed in detail below may be implemented in any of numerous ways, as the described concepts are not limited to any particular manner of implementation. Examples of specific implementations and applications are provided primarily for illustrative purposes. Although illustrative examples as applied to DWI imaging are presented, the disclosed approaches are applicable to other multi-shot MR imaging modalities.

DWI imaging techniques may be utilized to image microscopic diffusivity, which may be particularly useful for investigating the white matter of the brain and performing a clinical assessment of diffusion within soft tissue. DWI imaging techniques utilize a combination of radiofrequency (RF) pulses and gradient magnetic fields to purposely wind and then rewind transverse magnetic spin phases, which results in each spin accruing a motion dependent phase. Incoherent motion, such as diffusion, manifests as spin phase incoherence, which induces cancellation of individual spin fields, and, ultimately, a decreased (e.g., diffusion weighted) electromagnetic signal level. The diffusion-caused signal loss may be viewed as an absolute image magnitude attenuation (scaling). This mechanism enables clinical assessment of diffusion, and is useful for various diagnostic processes.

Although DWI data may be acquired with single-shot pulse sequences, such as single-shot echo-planar imaging (EPI), such single-shot DWI techniques are limited in spatial resolution, which introduces challenges when measuring detailed diffusion properties in fine structures where high spatial resolution is required. To address these limitations, multi-shot techniques may be utilized to address the amplified shot-to-shot motion-induced phase variations and produce adequate high-resolution DWI data. Multi-shot DWI acquisition techniques involve multiple spatially encoded acquisitions, as opposed to single-shot, where an entire two-dimensional (2D) or 3D image would be encoded and acquired with a single excitation and single train of acquisitions.

All motion, regardless of its source and spin coherency, contributes to the phase accrual during DWI imaging. Coherent spin motion from various sources (e.g., patient movements such as respiration, convulsion, etc.), accumulates coherent spin phase, which differentiates it from diffusion and does not induce signal cancellation. The coherent phase therefore remains at the time of signal acquisition after the diffusion encoding module and exhibits as extra phase components on complex MR images (e.g., a motion phase map). Such phase maps are motion-dependent and may cause data inconsistency for certain types of acquisitions.

Clinical DWI images may be noisy. For diffusion sensitivity, MR imaging systems may utilize a high b-value (the metric of diffusion weighting, which quantitatively describes the amount of spin “winding” and “rewinding”) that substantially attenuates the signal. Three-dimensional (3D) imaging may also be utilized to boost DWI signal-to-noise-ratio (SNR), which typically requires multi-shot acquisition. Multi-shot acquisition techniques complicate DWI image reconstruction processes because changing patient motion across different shots causes phase inconsistency. Phase-navigation may be utilized to handle such phase inconsistency at image reconstruction, enabling successful reconstruction of the shot-invariant diffusion weighted image.

Model-based phase-navigated DWI reconstruction utilizes explicit knowledge of motion phase maps at each shot to establish the Fourier transform (FT) linear mapping between acquired k-space data of each shot and the diffusion-weighted image that may be modulated by the shot specific motion phase maps. The phase maps are generally estimated using partial or entire data of each shot (e.g., navigator data), particularly for in vivo scanning.

The systems and methods described herein provide motion phase map estimation techniques that are independent of a particular navigator data acquisition strategy. Arbitrary structural image data from the same subject of a DWI scan to be corrected is utilized, exploiting that two aligned complex images are mutually convertible using their ratio image (the voxel-wise division of two images), which is referred to herein as a “navigator map.” This image domain voxel-wise relation may also be compactly captured in the k-space as a convolution. The estimation of a navigator map may be formulated as a regularized minimization problem, and therefore the phase of the outcome may be utilized as the motion phase maps for phase-navigated reconstruction. The magnitude map of an estimated navigator map for may be utilized to detect shots with excessive motion that should be rejected and re-acquired.

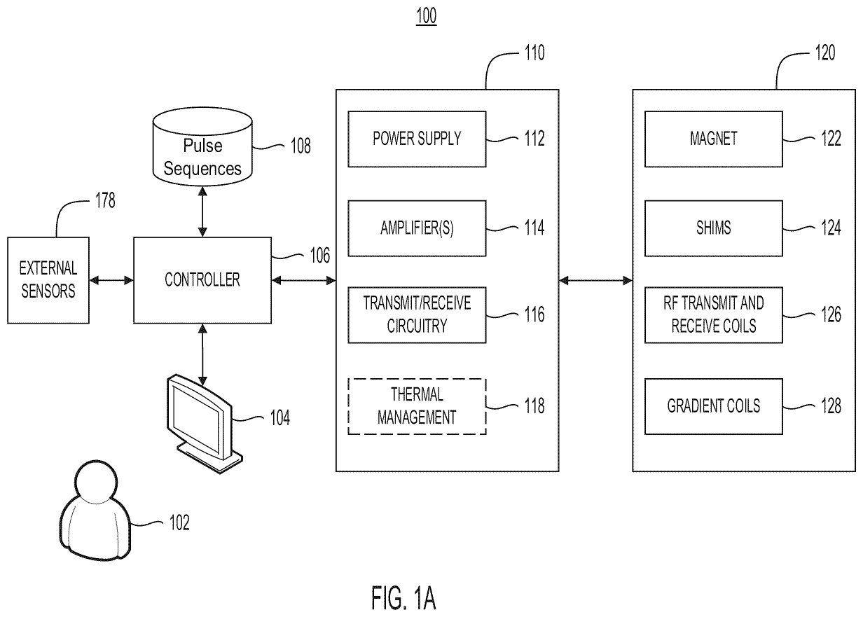

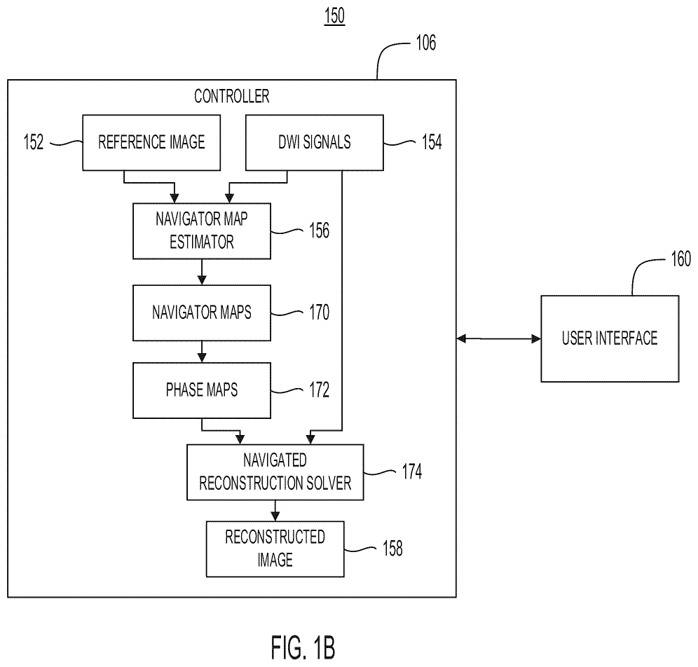

FIG. 1A illustrates an example MRI system which may be utilized in connection with the navigator map estimation techniques described herein. In FIG. 1A, MRI system 100 may include a computing device 104, a controller 106, a pulse sequences repository 108, a power management system 110, and magnetics components 120. The MRI system 100 is illustrative, and an MRI system may have one or more other components of any suitable type in addition to or instead of the components illustrated in FIG. 1A. Additionally, the implementation of components for a particular MRI system may differ from those described herein. Examples of low-field MRI systems may include portable MRI systems, which may have a field strength that may be, in a non-limiting example, less than or equal to 0.5 T, that may be less than or equal to 0.2 T, that may be within a range from 1 mT to 100 mT, that may be within a range from 50 mT to 0.1 T, that may be within a range of 40 mT to 80 mT, that may be about 64 mT, etc.

The magnetics components 120 may include B₀ magnets 122, shims 124, radio frequency (RF) transmit and receive coils 126, and gradient coils 128. The B₀ magnets 122 may be used to generate a main magnetic field B₀. B₀ magnets 122 may be any suitable type or combination of magnetics components that may generate a desired main magnetic B₀ field. In some embodiments, B₀ magnets 122 may be one or more permanent magnets, one or more electromagnets, one or more superconducting magnets, or a hybrid magnet comprising one or more permanent magnets and one or more electromagnets or one or more superconducting magnets. In some embodiments, B₀ magnets 122 may be configured to generate a B₀ magnetic field having a field strength that may be less than or equal to 0.2 T or within a range from 50 mT to 0.1 T.

In some implementations, the B₀ magnets 122 may include a first and second B₀ magnet, which may each include permanent magnet blocks arranged in concentric rings about a common center. The first and second B₀ magnet may be arranged in a bi-planar configuration such that the imaging region is located between the first and second B₀ magnets. In some embodiments, the first and second B₀ magnets may each be coupled to and supported by a ferromagnetic yoke configured to capture and direct magnetic flux from the first and second B₀ magnets.

The gradient coils 128 may be arranged to provide gradient fields and, in a non-limiting example, may be arranged to generate gradients in the B₀ field in three substantially orthogonal directions (X, Y, and Z). Gradient coils 128 may be configured to encode emitted MR signals by systematically varying the B₀ field (the B₀ field generated by the B₀ magnets 122 or shims 124) to encode the spatial location of received MR signals as a function of frequency or phase. In a non-limiting example, the gradient coils 128 may be configured to vary frequency or phase as a linear function of spatial location along a particular direction, although more complex spatial encoding profiles may also be provided by using nonlinear gradient coils. In some embodiments, the gradient coils 128 may be implemented using laminate panels (e.g., printed circuit boards), in a non-limiting example.

MRI scans are performed by exciting and detecting emitted MR signals using transmit and receive coils, respectively (referred to herein as radio frequency (RF) coils). The transmit and receive coils may include separate coils for transmitting and receiving, multiple coils for transmitting or receiving, or the same coils for transmitting and receiving. Thus, a transmit/receive component may include one or more coils for transmitting, one or more coils for receiving, or one or more coils for transmitting and receiving. The transmit/receive coils may be referred to as Tx/Rx or Tx/Rx coils to generically refer to the various configurations for transmit and receive magnetics components of an MRI system. These terms are used interchangeably herein. In FIG. 1A, RF transmit and receive coils 126 may include one or more transmit coils that may be used to generate RF pulses to induce an oscillating magnetic field Bi. The transmit coil(s) may be configured to generate any type of suitable RF pulses.

The power management system 110 includes electronics to provide operating power to one or more components of the MRI system 100. In a non-limiting example, the power management system 110 may include one or more power supplies, energy storage devices, gradient power components, transmit coil components, or any other suitable power electronics needed to provide suitable operating power to energize and operate components of MRI system 100. As illustrated in FIG. 1A, the power management system 110 may include a power supply system 112, power component(s) 114, transmit/receive circuitry 116, and may optionally include thermal management components 118 (e.g., cryogenic cooling equipment for superconducting magnets, water cooling equipment for electromagnets).

The power supply system 112 may include electronics that provide operating power to magnetic components 120 of the MRI system 100. The electronics of the power supply system 112 may provide, in a non-limiting example, operating power to one or more gradient coils (e.g., gradient coils 128) to generate one or more gradient magnetic fields to provide spatial encoding of the MR signals. Additionally, the electronics of the power supply system 112 may provide operating power to one or more RF coils (e.g., RF transmit and receive coils 126) to generate or receive one or more RF signals from the subject. In a non-limiting example, the power supply system 112 may include a power supply configured to provide power from mains electricity to the MRI system or an energy storage device. The power supply may, in some embodiments, be an AC-to-DC power supply that converts AC power from mains electricity into DC power for use by the MRI system. The energy storage device may, in some embodiments, be any one of a battery, a capacitor, an ultracapacitor, a flywheel, or any other suitable energy storage apparatus that may bi-directionally receive (e.g., store) power from mains electricity and supply power to the MRI system. Additionally, the power supply system 112 may include additional power electronics including, but not limited to, power converters, switches, buses, drivers, and any other suitable electronics for supplying the MRI system with power.

The amplifiers(s) 114 may include one or more RF receive (Rx) pre-amplifiers that amplify MR signals detected by one or more RF receive coils (e.g., coils 126), one or more RF transmit (Tx) power components configured to provide power to one or more RF transmit coils (e.g., coils 126), one or more gradient power components configured to provide power to one or more gradient coils (e.g., gradient coils 128), and may provide power to one or more shim power components configured to provide power to one or more shims (e.g., shims 124). In some implementations, the shims 124 may be implemented using permanent magnets, electromagnetics (e.g., a coil), or combinations thereof. The transmit/receive circuitry 116 may be used to select whether RF transmit coils or RF receive coils are being operated.

As illustrated in FIG. 1A, the MRI system 100 may include the controller 106 (also referred to as a console), which may include control electronics to send instructions to and receive information from power management system 110. The controller 106 may be configured to implement one or more pulse sequences, which are used to determine the instructions sent to power management system 110 to operate the magnetic components 120 in a desired sequence (e.g., parameters for operating the RF transmit and receive coils 126, parameters for operating gradient coils 128, etc.). Additionally, the controller 106 may execute processes to estimate navigator maps for DWI reconstruction according to various techniques described herein. A pulse sequence may generally describe the order and timing in which the RF transmit and receive coils 126 and the gradient coils 128 operate to acquire resulting MR data. In a non-limiting example, a pulse sequence may indicate an order and duration of transmit pulses, gradient pulses, and acquisition times during which the receive coils acquire MR data.

A pulse sequence may be organized into a series of periods. In a non-limiting example, a pulse sequence may include a pre-programmed number of pulse repetition periods, and applying a pulse sequence may include operating the MRI system in accordance with parameters of the pulse sequence for the pre-programmed number of pulse repetition periods. In each period, the pulse sequence may include parameters for generating RF pulses (e.g., parameters identifying transmit duration, waveform, amplitude, phase, etc.), parameters for generating gradient fields (e.g., parameters identifying transmit duration, waveform, amplitude, phase, etc.), timing parameters governing when RF or gradient pulses are generated or when the receive coil(s) are configured to detect MR signals generated by the subject, among other functionality. In some embodiments, a pulse sequence may include parameters specifying one or more navigator RF pulses, as described herein.

Examples of pulse sequences include zero echo time (ZTE) pulse sequences, balance steady-state free precession (bSSFP) pulse sequences, gradient echo pulse sequences, inversion recovery pulse sequences, DWI pulse sequences, spin echo pulse sequences including conventional spin echo (CSE) pulse sequences, fast spin echo (FSE) pulse sequences, turbo spin echo (TSE) pulse sequences or any multi-spin echo pulse sequences such a diffusion weighted spin echo pulse sequences, inversion recovery spin echo pulse sequences, arterial spin labeling pulse sequences, and Overhauser imaging pulse sequences, among others.

As illustrated in FIG. 1A, the controller 106 may communicate with the computing device 104, which may be programmed to process received MR data. In a non-limiting example, the computing device 104 may process received MR data to generate one or more MR images using any suitable image reconstruction processes, including the execution of techniques involving the estimation of navigator maps for DWI data, as described herein. Additionally or alternatively, the controller 106 may process received MR data to perform DWI reconstruction based on the techniques described herein. The controller 106 may provide information about one or more pulse sequences to computing device 104 for the processing of data by the computing device. In a non-limiting example, the controller 106 may provide information about one or more pulse sequences to the computing device 104 and the computing device 104 may estimate navigator maps and perform DWI reconstruction based, at least in part, on the provided information.

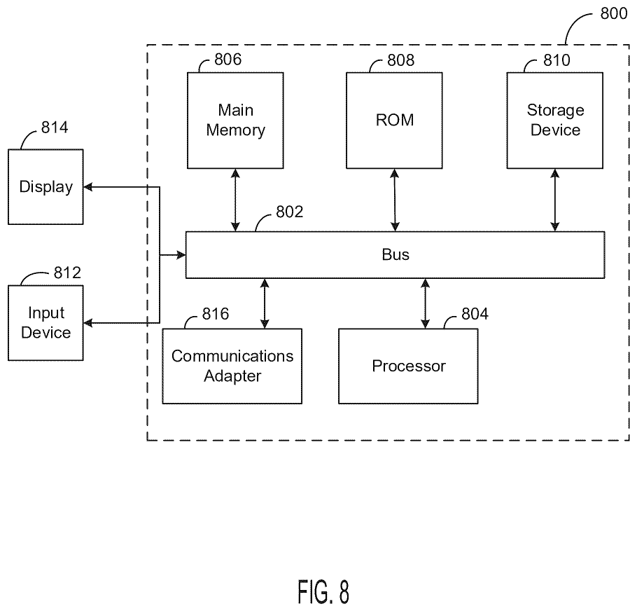

The computing device 104 may be any electronic device configured to process acquired MR data and generate one or more images of a subject being imaged. The computing device 104 may include at least one processor and a memory (e.g., a processing circuit). The memory may store processor-executable instructions that, when executed by a processor, cause the processor to perform one or more of the operations described herein. The processor may include a microprocessor, an application-specific integrated circuit (ASIC), a field-programmable gate array (FPGA), a graphics processing unit (GPU), a tensor processing unity (TPU), etc., or combinations thereof. The memory may include, but is not limited to, electronic, optical, magnetic, or any other storage or transmission device capable of providing the processor with program instructions. The memory may further include a floppy disk, CD-ROM, DVD, magnetic disk, memory chip, ASIC, FPGA, read-only memory (ROM), random-access memory (RAM), electrically erasable programmable ROM (EEPROM), erasable programmable ROM (EPROM), flash memory, optical media, or any other suitable memory from which the processor may read instructions. The instructions may include code generated from any suitable computer programming language. The computing device 104 may include any or all of the components and perform any or all of the functions of the computer system 800 described in connection with FIG. 8. In some implementations, the computing device 104 may be located in a same room as the MRI system 100 or coupled to the MRI system 100 via wired or wireless connection.

In some implementations, computing device 104 may be a fixed electronic device such as a desktop computer, a server, a rack-mounted computer, or any other suitable fixed electronic device that may be configured to process MR data and generate one or more images from DWI signals. Alternatively, computing device 104 may be a portable device such as a smart phone, a personal digital assistant, a laptop computer, a tablet computer, or any other portable device that may be configured to process DWI data according to the techniques described herein. In some implementations, computing device 104 may comprise multiple computing devices of any suitable type, as aspects of the disclosure provided herein are not limited in this respect. In some implementations, operations that are described as being performed by the computing device 104 may instead be performed by the controller 106, or vice-versa. In some implementations, certain operations may be performed by both the controller 106 and the computing device 104 via communications between said devices.

The MRI system 100 may include one or more external sensors 178. The one or more external sensors may assist in detecting one or more error sources (e.g., motion, noise) which degrade image quality. The controller 106 may be configured to receive information from the one or more external sensors 178. In some embodiments, the controller 106 of the MRI system 100 may be configured to control operations of the one or more external sensors 178, as well as collect information from the one or more external sensors 178. The data collected from the one or more external sensors 178 may be stored in a suitable computer memory and may be utilized to assist with various processing operations of the MRI system 100.

As described herein above, the techniques described herein may be utilized to estimate motion phase maps for DWI data that are independent of a particular navigator data acquisition strategy. Reference image data from the same subject of a DWI scan to be corrected may be utilized to exploit that two aligned complex images are mutually convertible using their ratio image (e.g., the voxel-wise division of two images). This image domain voxel-wise relation may also be compactly captured in the k-space as a convolution. The navigator maps may be estimated using regularized minimization techniques, with the phase of the output being utilized as the motion phase maps for phase-navigated reconstruction. Additionally, the magnitude maps of estimated navigator maps may be utilized to detect shots with excessive motion that should be rejected and re-acquired.

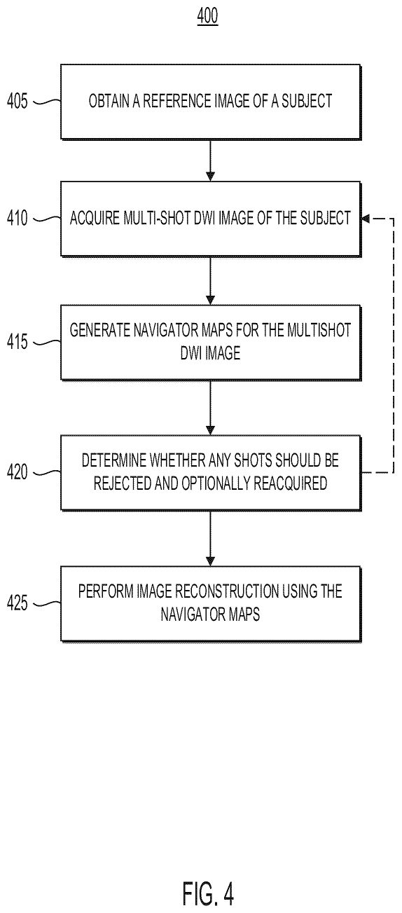

FIG. 1B illustrates an example system 150 for estimating navigator maps for DWI image reconstruction, in accordance with one or more implementations. In a non-limiting example, the system 150 may be used to perform all or part of the example method 400 described in connection with FIG. 4, as well as any other operations described herein. In some implementations, the system 150 forms a portion of an MRI system, such as MRI system 100 described in connection with FIG. 1A. In some implementations, the system 150 is external to an MRI system but communicates with the MRI system (or components thereof) to perform the example method 400 of FIG. 4 as described herein.

As shown in FIG. 1B, an embodiment of the system 150 may include the controller 106 and a user interface 160. In some implementations, the functionality of the controller 106 as described in connection with FIG. 1B may be implemented on a computing device in communication with the controller 106, such as the computing device 104 described in connection with FIG. 1A. The user interface 160 may present or enable inspection of any of the DWI signals, reference images, or reconstructed DWI images described herein. The user interface 160 may provide input relating to the performance of DWI image reconstruction techniques, in a non-limiting example, by receiving input or configuration data relating to the estimation of navigator maps, the performance of MR scans, or the utilization of reference images for a particular subject.

The user interface 160 may allow a user to select a type of imaging to be performed by the MRI system (e.g., diffusion-weighted imaging, etc.), select a sampling density for the MR scan, or to define any other type of parameter relating to MR imaging or model training as described herein. In some implementations, the user interface 160 may display, via a display in communication with the user interface 160, DWI signal data, reference images, or reconstructed DWI data generated using the techniques described herein. The user interface 160 may allow a user to initiate imaging by the MRI system, or to execute or coordinate any of the estimation techniques described herein.

The controller 106 may control aspects of the example system 150, in a non-limiting example to perform at least a portion of the example method 400 described in connection with FIG. 4, as well as any other operations described herein. In some implementations, the controller 106 may control one or more operations of the MRI system, such as the MRI system 100 described in connection with FIG. 1A. Additionally or alternatively, the computing device 104 of FIG. 1A may perform some or all of the functionality of the controller 106. In such implementations, the computing device 104 may be in communication with the controller 106 to exchange information as necessary to achieve desired results.

The controller 106 may be implemented using software, hardware, or a combination thereof. The controller 106 may include at least one processor and a memory (e.g., a processing circuit). The memory may store processor-executable instructions that, when executed by a processor, cause the processor to perform one or more of the operations described herein. The processor may include a microprocessor, an ASIC, an FPGA, a GPU, a TPU, etc., or combinations thereof. The memory may include, but is not limited to, electronic, optical, magnetic, or any other storage or transmission device capable of providing the processor with program instructions. The memory may further include a floppy disk, CD-ROM, DVD, magnetic disk, memory chip, ASIC, FPGA, ROM, RAM, EEPROM, EPROM, flash memory, optical media, or any other suitable memory from which the processor may read instructions. The instructions may include code generated from any suitable computer programming language. The controller 106 may include any or all of the components and perform any or all of the functions of the computer system 800 described in connection with FIG. 8.

The controller 106 may be configured to perform one or more functions described herein. The controller 106 may store or capture a reference image 152 of a subject. The reference image 152 may be an image of a subject that captures the same portion as a corresponding set of DWI signals 154 (e.g., which make up a multi-shot interleaved DWI of the same subject). The reference image 152 may be a zero b-value DWI scan image, and may be a complex reference image that may be well aligned with the corresponding set of DWI signals 154. In a non-limiting example, at a low image-resolution level, the reference image 152 may fully (or partially beyond a predetermined threshold) overlap with the multi-shot DWI signals 154 that are to-be-reconstructed using the techniques described herein. In some implementations, the reference image may be an image with different contrast (e.g., T1, T2, proton density, fluid-attenuated inversion recovery (FLAIR), etc.), a combination of reference images, or an image scanned for calibration purposes, among others. In some implementations, the reference image 152 can be optimized for a subject contrast. A given base type of sequence can be optimized to produce different types of contrast. In a non-limiting example, contrast can be optimized by modifying timings within the sequence like TE (time echo), TR (repetition time), echo train length, or inversion time, among others. Optimization may also be performed by adding or removing RF pulses, or varying parameters within a sequence. Such techniques may be utilized to create different types of image contrast to using the same basic kind of sequence. Non-limiting examples of sequences include T1-weighted, T2-weighted, FLAIR, water/fat separated, fat suppressed, phase contrast, or blood contrast, among others. Contrast in MRI refers to the relative image intensities of different tissues (e.g., white matter, gray matter). Such intensities are controlled by the image sequence used (e.g., DWI, T1, T2, etc.) to manifest different pathologies to-be diagnosed.

The reference image may be utilized in connection with the techniques described herein to estimate navigator maps for the set of DWI signals 154. The set of DWI signals 154 may include shots of a multi-shot interleaved DWI scan of a subject. The DWI signals 154 may collectively capture a region of a subject that may also be depicted in the corresponding reference image 152. In some implementations, the DWI signals 154 may be acquired using the same coil sensitivity profile as that of the reference image 154. This may apply to virtual coil sensitivity profiles obtained from, coil compression and pre-whitening, in a non-limiting example. Multi-shot imaging refers to splitting the acquisition of MRI data (e.g., the DWI data) into multiple readouts. The DWI signals 154 may include data in the k-space (e.g., frequency-domain), which may be reconstructed using the techniques described herein to obtain a spatial-domain (or “image domain”) image. Multi-shot DWI signals 154 may be utilized to image a subject when a sufficient portion of k-space data cannot be fully covered by a single readout (single-shot).

Multi-shot DWI images divide the image into segments, acquiring one at a time and once per shot. This composition scheme for the DWI signals 154 may be vulnerable to motion. In a non-limiting example, if the subject being imaged at a different state for each shot, the composed “sufficient” portion could be a mixture, and may leave artefacts in the reconstructed image. Typical patient motion may include gross motion of the body part being imaged, physiological motion, or motion of distal parts of the body (reaching into the imaging field of view, in a non-limiting example), among others. Besides motion, other potential causes of phase variation across shots of the DWI signals 154 include changes in the scanner magnetic or RF fields (e.g., eddy currents, hysteresis, movement of metal objects in or near the scanner, heating of electronics or magnetic components, etc.). Although the techniques described herein provide examples where the reconstructed multi-shot MR images are DWI MR images, it should be understood that the techniques described herein are not limited solely to multi-shot DWI images, and indeed may be implemented with any type of multi-shot MR image.

The DWI signals 154 may be captured by any suitable MR imaging technique (e.g., via the MR system 100). In a non-limiting example, the DWI signals 154 may be captured using a low-field MR system. In some implementations, pulse sequences such as diffusion-weighted steady state free precession (DW-SSFP) sequences, which may be specifically designed for use or optimal performance in the low-field context, may be utilized to generate the set of DWI signals 154. The set of DWI signals 154 may also be captured using other types of MR imaging systems. Each DWI signal of the set of DWI signals 154 may correspond to a single shot of multi-shot interleaved DWI. Each shot of the set of DWI signals 154 may correspond to a high b-value image (as a non-limiting example, a b-value that may be greater than the b-value of the reference image 152). Both the set of DWI signals 154 and the corresponding reference image 152 may be provided as input to the navigation map estimator 156, which may generate a respective navigator map for each shot in the set of DWI signals 154. The reference image 152 may have a different phase than the DWI signals 154.

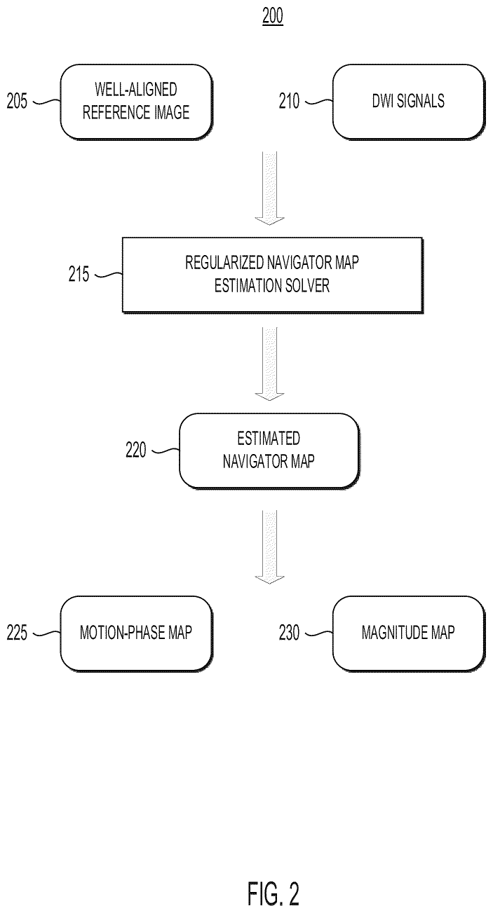

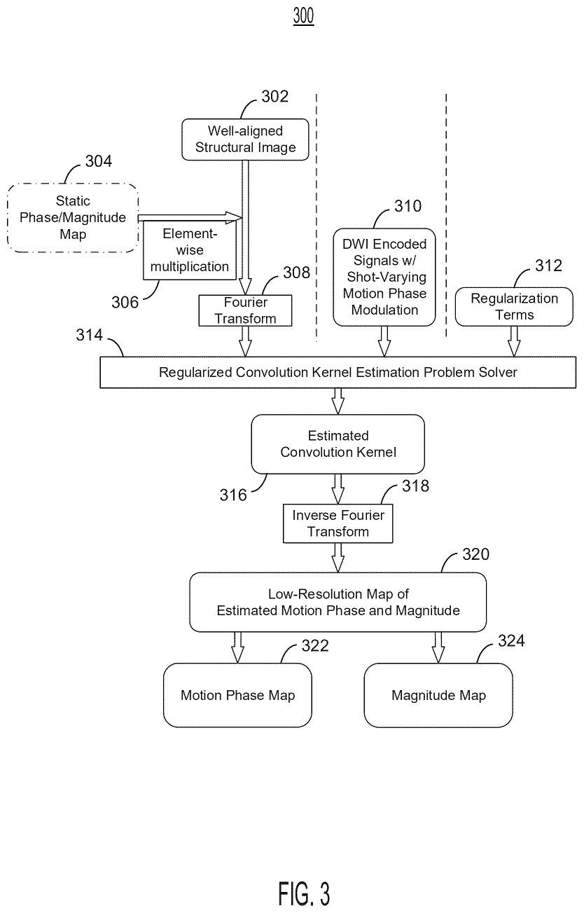

The controller 106 may include a navigator map estimator 156, which may estimate a navigator map for each shot in the set of DWI signals 154 using the reference image 152. The navigator map estimator 156 may be implemented in hardware, software, or a combination of hardware and software. The navigator map estimator 156 may generate the navigator maps 170 using the techniques described herein, which may include a phase component and a magnitude component. The phase component may be extracted from the navigator maps 28- and represented as the phase maps 172. The phase maps 172 and the DWI signals 154 may be provided as input to the navigated reconstruction solver 174, which may apply the estimated navigator maps 170 to the DWI signals 154 to generate the reconstructed image 158 by solving Formulation 5 described in further detail herein. The navigator maps 170 may be similar to the estimated navigator maps 220 or the low-resolution maps of estimated motion phase and magnitude 320 described in connection with FIGS. 2 and 3, respectively. The phase maps 172 may be similar to or the same as the phase map 225 (FIG. 2) and motion phase map 322 (FIG. 3). The navigator maps 170 may be generated using the techniques described herein.

To estimate the navigator maps 170, the navigator map estimator 156 may perform a regularized optimization to estimate the ratio image of the reference image and a respective shot of the DWI signals 154 (e.g., the voxel-wise division of both images). This image domain voxel-wise relation may also be compactly captured in the k-space as a convolution. The estimation of the navigator maps 170 is performed as a regularized minimization problem, with the phase of the outcome utilized as the motion phase maps 172 for phase-navigated reconstruction. The magnitude map of the estimated navigator maps may be utilized for detecting shots with excessive motion that should be rejected and re-acquired. The estimation process for the navigator maps 170 is further described herein. In some implementations, the DWI signals 154 may themselves indicate excessive motion for shots to be rejected. In some implementations, data from the external sensors 178 may indicate excessive motion (e.g., vibration sensors, accelerometers, gyroscopes, etc.). Excessive motion may be any amount of motion or acceleration that exceeds a predetermined or configured threshold.

Respective navigator maps 170 may be estimated for each shot in the DWI signals 154. The phase component of the navigator maps 170 (the phase maps 172 or the “motion-phase maps 172”) may be applied to the DWI signals 154 by the navigated reconstruction solver 174 to generate the reconstructed image 158. The navigated reconstruction solver 174 may include hardware, software, or combinations of hardware and software that optimize Formulation 5, as described in detail herein, to generate the reconstructed image 158. Motion-phase may be primarily a concept of DWI. In the context of DWI, depending on the extent of imaging subject movements, motion may be categorized as either bulk motion or small motion. Small motion refers to movements that are sub-pixel or sub-voxel (e.g., movement that may be not great enough to shift into another pixel). As such, for small motion, the pixel value magnitude does not change. The pixel value phase does change due to the physics of DWI. These phase changes cause data inconsistencies for multi-shot DWI, which may be corrected using the navigator maps that are estimated by the navigator map estimator 156 using the techniques described herein.

Once the navigator maps for the DWI signals 154 have been estimated, the navigator map estimator 156 may perform navigated reconstruction to reconstruct images from the DWI signals 154. In the context of DWI, navigated reconstruction refers to reconstructing a DWI image in a way that the motion-phase data inconsistencies are removed or mitigated, such that inconsistencies are less-pronounced in the reconstructed image. Navigated-reconstruction method may be performed by solving Formulation 5, as described herein below, using the motion-phase maps 172 of the respective navigator maps 170 to respective shots of the DWI signals 154. The reconstruction techniques performed by the navigated reconstruction solver 174 may be referred as “self-navigated,” because the techniques described herein need not rely on external data (e.g., other instruments to measure the motion-phase map).

Once the navigator maps 170 have been utilized to generate the reconstructed image 158, may the reconstructed image 158 may be stored in memory of the controller 106 or another computing device (e.g., the computing device 104). The reconstructed image 158 may then be presented on the user interface 160 or transmitted to another computing device, in a non-limiting example. The image reconstruction techniques described herein may be self-navigated techniques, because external data (e.g., from external instruments that somehow measure the motion-phase map) may not be required to perform image reconstruction.

FIG. 2 depicts an example dataflow diagram 200 of an example process for estimating navigator maps for DWI image reconstruction, in accordance with one or more implementations. The estimation process shown in the diagram 200 may be performed, in a non-limiting example, by any computing device described herein, such as the controller 106, computing device 104, or the computer system 800, among others. The estimation process shown in the diagram 200 may be utilized to estimate navigator maps 220, which may be used to reconstruct diffusion-weighted images or determine whether certain shots of a multi-shot interleaved diffusion-weighted image must be reacquired for proper reconstruction.

To estimate navigator maps 220 for the DWI encoded signals 210, both a reference image 205 that may be well-aligned (e.g., completely or partially overlapping above a predetermined threshold) and the DWI encoded signals 210 may be provided as input to a regularized navigator map reconstruction solver 215 (e.g., which may be similar to and include any of the structure or functionality of the navigator map estimator 156). The regularized navigator map reconstruction solver 215 may perform an estimation process to generate the estimated navigator map 220, which may include both a motion-phase map 225 and a magnitude map 230 components.

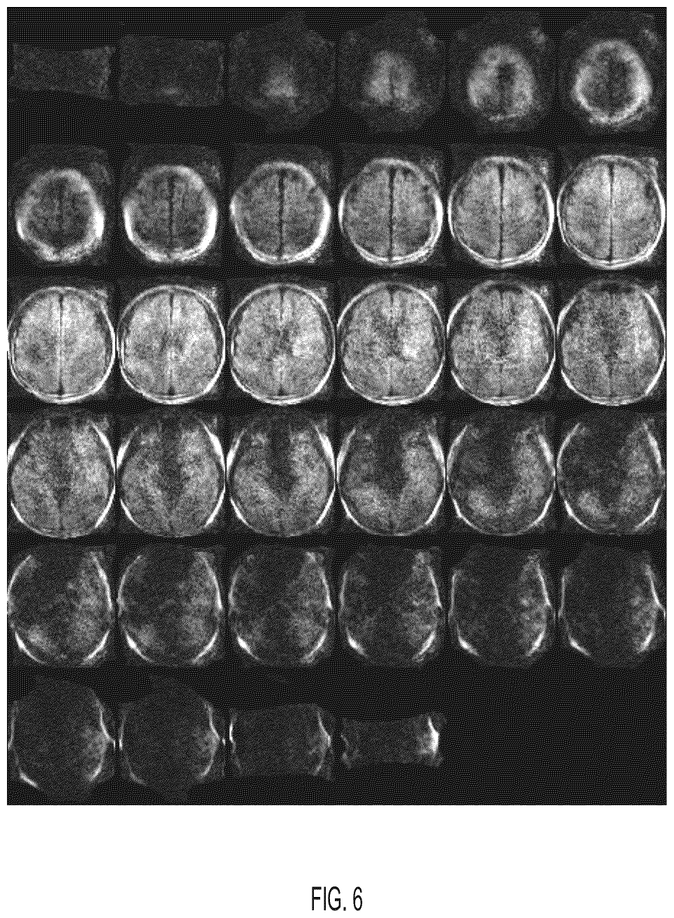

The reference image 205 may be an image of a subject that captures the same portion as the corresponding DWI encoded signals 210. The reference image 205 may be a zero b-value DWI scan image. The reference image 210 may be well-aligned, such that at a low image-resolution level, the reference image 205 may fully (or partially beyond a predetermined threshold) overlap with the multi-shot DWI signals 210 that are to-be-reconstructed using the techniques described herein. In some implementations, an image registration process may be performed to align the reference image 205 with the corresponding DWI signals 210. The image registration process may be performed between the reference image and a reconstructed version of the DWI encoded signals 210 in the image domain (e.g., without any correction, such as the DWI image shown in FIG. 6, etc.). The results of the image registration process may be a transformation (e.g., a rotation, translation) of the reference image that aligns the reference image 205 with the image corresponding to the DWI encoded signals 210. The transformation may be applied to the reference image 205 to create the well-aligned reference image, which may be provided as input to the regularized navigator map estimation solver 215.

As described herein, the reference image 205 may be an image with different contrast (e.g., T1, T2, proton density, fluid-attenuated inversion recovery (FLAIR), etc.), a combination of reference images, or an image scanned for calibration purposes, among others. Contrast in MRI refers to the relative image intensities of different tissues (e.g., white matter, gray matter). Such intensities are controlled by the image sequence used (e.g., DWI, T1, T2, etc.) to manifest different pathologies to-be diagnosed. Images from different MRI sequences may intrinsically have different phases. As a consequence, the reference image 205, which may be obtained from a different sequence than the DWI signals 210, may have a different phase from that of the DWI signals 210. This phase difference may be a static phase difference (sometimes referred to as a shot-invariant phase difference). In some implementations, a static phase or magnitude map may be applied to the reference image 205 (e.g., via element-wise multiplication) to account for this shot-invariant phase difference. The navigator maps 220 generated by the navigator map reconstruction solver 215 may be utilized to correct for shot-variant phase differences between the reference image 205 and the DWI signals 210.

To estimate the navigator maps 220 for the DWI signals 210, the navigator map reconstruction solver 215 may perform a regularized optimization process. The theory regarding the optimization process to estimate the navigator maps 220 may be provided as follows. First, the DWI signals 210 and the well-aligned reference image 205 may be acquired using suitable MR imaging techniques. This may be satisfied at little cost for a high b-value DWI scan, as DWI in practice may be part of a protocol with a structural imaging sequence, such as a zero b-value DWI scan. The zero b-value DWI scan provide a zero b-value image, which may be utilized as the reference image 205. Although this example describes the process in the context of a zero b-value image as the reference image 205, it should be understood that the reference image 205 may also be an image of the subject with different contrast (e.g., T1, T2, proton density, FLAIR), a combination of reference images, or may be an image scanned for calibration purposes.

The estimation process may assume a smooth motion phase map and negligible presence of bulk motion (e.g., significant motion that produces substantial misalignment against the reference image) during the DWI scan. The DWI image may be modeled as three components: a well-aligned structural image, multiplied by a shot-invariant scaling map, and then multiplied again by a shot-specific motion phase map. The shot-invariant scaling map describes tissue-dependent contrast variations between the reference and subject images. Mathematically, this multiplicative relationship may be expressed as the following Equation 1. In Equation 1, for an N-sized discrete image, at shot s, the high b-value image, x_{b,s} (e.g., the DWI signals 210, each of which may correspond to a respective shot of a corresponding DWI image), equals the product of a zero b-value image, x₀ (e.g., the reference image 205), a shot-invariant absolute magnitude attenuation map, a, and a motion phase map, pₛ.

$${x}_{b , s} = {x}_{0} ⊙ a ⊙ {p}_{s} = {x}_{0} ⊙ {h}_{s} , \qquad ( 1 )$$

In Equation 1 above, {x_{b,s}, x₀, a, pₛ}ϵ [symbol] ^{N}, ⊚ denotes element-wise multiplication; and hₛ:=a⊚pₛϵ [symbol] ^{N} denotes the navigator map 220 to be estimated. Formulation 2 below provides the navigator map 220 estimation process performed by the navigator map reconstruction solver 215. In Formulation 2, \tilde{x}_{b,s}ϵ [symbol] ^{N}^{ₛ} denotes the k-space Nₛ-sized (full or partial) DWI signal 210 that corresponds to the shot image x_{b,s}.

$${arg}_{g} min {‖ {F}_{s} diag ( {x}_{0} ) B g - {\tilde{x}}_{b , s} ‖}_{2}^{2} + λ R ( g ) \qquad ( 2 )$$

In Formulation 2 above, Fₛϵ [symbol] ^{N}^{ₛ}^{×N} denotes a partial Fourier transform that maps the reference image 205 to the acquired k-space locations of the shot; the operator diag(⋅) arranges an N-sized image as a N×N-sized diagonal matrix; Bϵ [symbol] ^{N×N}^{_{g}} is a set of image vectors, from which, with the coefficients gϵ [symbol] ^{N}^{_{g}}, an estimation of the navigator map 220 as ĥₛ:=Bgϵ [symbol] ^{N} is calculated; and R(g) includes regularization(s) on λ≥0 with tuning coefficients. For brevity, subscripting of B, g, R and λ with s has been omitted. Formulation 2 may be generalized to multi-coil acquisition scenarios, which involves substitution of {x₀, \tilde{x}_{b,s}} with their coil-specific counterparts, and summation of the LS fitting error across coils. Multi-coil acquisition acts as a data enhancement to the estimation, as g is invariant across coils.

Formulation (2) remarks the image domain roles of variables, and may facilitate incorporation of image domain priors into the design of regularizers, in a non-limiting example. In the context of k-space data, Formulation 3 below utilizes the identity F^{H}F=I to manifest the k-space convolution between x₀ and the estimated navigator map Bg, enabling incorporation of k-space priors.

$${arg}_{g} min {‖ {F}_{s} diag ( {x}_{0} ) {F}^{H} FBg - {\tilde{x}}_{b , s} ‖}_{2}^{2} + λ R ( g ) \qquad ( 3 )$$

In a non-limiting example based on Formulation 3, let B be a set of linear phase unitary vectors such that FB arranges the elements in g to the center of k-space, where the design of g is effectively estimating the k-space center of hₛ. The techniques described herein are independent of any particular navigator data acquisition strategy. Using the center of k-space for estimation may be more robust, as it may be the region with highest signal magnitude, and has a larger correlation with the convolution kernel to be estimated. Once the solution to g, is found, it may be zero-padded to size N, which may then be inverse-Fourier transformed to obtain the navigator map 220 estimation, ĥₛ.

For this k-space design example, regularizers may be chosen based on a number of different criteria. Although certain regularizers are described herein, it should be understood that any suitable regularizer may be utilized to achieve desired results. Empirically, the k-space of the true navigator map, \tilde{h}ₛ, is compact (e.g., most of its energy concentrates near the center of the k-space), which resembles properties of the Fourier transform of general structural images. Therefore, the regularizer R(g)=∥Dg∥₂², may be utilized in connection with these techniques, where Dϵ [symbol] ^{N}^{_{g}}^{×N}^{_{g}} is a diagonal matrix with non-negative elements, such that it encourages the energy of g to concentrate towards the very center of k-space. D may be constructed according to Equation 4 below.

$$D = diag ( f / max ( f ) ) , \qquad ( 4 )$$

$$f := crop ( {( \vert {\tilde{x}}_{0} \vert + flip ( \vert {\tilde{x}}_{0} \vert ) )}^{- 0.35} )$$

In Equation 4 above, crop(⋅) extracts the N_{g}-sized center from its operands, flip(⋅) flips its (k-spatial) operand in all axes, and |⋅| takes the magnitude element-wisely. The value for λ may be chosen such that it is proportional to the largest singular value of the LS term matrix. The value may vary across applications.

Once the navigator map 220 has been estimated using the techniques described herein above the motion-phase map 225 may be utilized to perform phase-navigated DWI reconstruction, which may be modeled below using Formulation 5 below.

$${arg}_{{x}_{b}} min {\sum }_{s} {‖ {E}_{s} ( {\hat{p}}_{s} ⊙ {x}_{b} ) - {y}_{s} ‖}_{2}^{2} + η P ( {x}_{b} ) \qquad ( 5 )$$

In Formulation 5 above, the phase component \hat{p}ₛ of ĥₛ (e.g., the estimated navigator map 220) is the motion phase map 225 estimation that may be utilized to solve for the shot invariant diffusion weighted image x_{b} (e.g., the reconstructed image 158). In Formulation 5, the yₛ is the acquired signal of each shot (e.g., a respective DWI signal 210), Eₛ is the corresponding MR signal encoding, and P regularizes the reconstructed image with weighting coefficient η. Additionally, the magnitude component of the estimated navigator map 220 is the magnitude map 230, which may be utilized to reject shots with excessive motion. In a non-limiting example, DWI signals 210 for which the estimated magnitude map 230 indicates excessive motion (e.g., a magnitude greater than a predetermined threshold, etc.) may be discarded, or otherwise flagged as exhibiting excessive motion. Shots that exhibit excessive motion may be reacquired and then re-processed using the techniques described herein.

FIG. 3 depicts an example dataflow diagram 300 of a process for estimating navigator maps for DWI image reconstruction based on k-space data, in accordance with one or more implementations. The estimation process shown in the diagram 300 may be performed, in a non-limiting example, by any computing device described herein, such as the controller 106, computing device 104, or the computer system 800, among others. The estimation process shown in the diagram 300 may be utilized to estimate navigator maps 320, which may be used to reconstruct diffusion-weighted images or to determine whether certain shots of a multi-shot interleaved diffusion-weighted image must be reacquired for proper reconstruction, as described herein.

The well-aligned structural image 302, along with the DWI encoded signals 310 (e.g., which include shot-varying motion-phase modulation that may be to be corrected) may be utilized in connection with regularization terms 312 (e.g., the terms described in connection with Formulation 4) to estimate a convolutional kernel 316 in the k-space. The convolutional kernel 316 may then applied to an inverse-Fourier transform 318 to generate the low-resolution map of estimated motion-phase and magnitude 320 (e.g., the estimated navigator map 220).

The well-aligned structural image 302 may be any image-domain reference image of a subject (e.g., the reference image 205, the reference image 152) that fully (or partially beyond a predetermined threshold) overlaps with the DWI encoded signals 310, as described herein. An optional static phase/magnitude map 304 may be applied to the well-aligned structural image 302 using an element-wise multiplication process 306. The well-aligned structural image 302, which includes data in the image domain, may be subjected to a Fourier transform 308 (e.g., a fast Fourier transform (FFT), other Fourier transform processes, etc.) to generate k-space data of the well-aligned structural image 302 in the frequency domain. The DWI encoded signals 310 may also include k-space data for multiple shots of a DWI image that may be to be corrected. The DWI encoded signals 310 may be suitable DWI data, such as high b-value image data in the frequency domain (e.g., k-space data). The DWI encoded signals 310 include shot-varying motion-phase modulation, as described herein. The DWI encoded signals 310 may correspond to a DWI image of the same subject as the well-aligned structural image 302.

The regularized convolution kernel estimation problem solver 314 may be executed by a suitable computer system (e.g., the controller 106, the computing device 104, the computer system 800, etc.) to estimate the convolutional kernel 316. The convolutional kernel 316 may a corresponding low-resolution map of the estimated motion phase and magnitude 320 represented in the frequency domain (e.g., k-space). The regularized convolution kernel estimation problem solver 314 may estimate the convolutional kernel 316 using the frequency-domain version of the well-aligned structural image 302 and the DWI encoded signals 310, as described herein. In a non-limiting example, the regularized convolution kernel estimation problem solver 314 may estimate the convolution kernel 316 using Formulation 3, as described herein. The regularization terms 312 may be any of the regularization terms described herein, and may be utilized in connection with the regularizer chosen to optimize the convolution kernel 316.

Once the convolution kernel 316 has been estimated using the techniques described herein, an inverse-Fourier transform 318 (e.g., with zero-padding, as needed) may be applied to the convolution kernel 316 to generate the estimated motion phase and magnitude map 320 (e.g., the navigator map 220, etc.). The motion-phase portion of the estimated motion phase and magnitude map 320 (the motion phase map 322) may be utilized in Formulation 5 to perform reconstruction of the DWI encoded signals 310 to generate a corrected DWI image. The magnitude portion of the estimated motion phase and magnitude map 320 (the magnitude map 324) may be utilized to reject certain shots of the DWI signals 310 that have excessive motion (e.g., those that indicate motion above a predetermined threshold).

FIG. 4 depicts a flowchart of an example method 400 of estimating a navigator map (e.g., the navigator map 220) for DWI data using a reference image and performing DWI image reconstruction using the navigator map, in accordance with one or more implementations. The method 400 may be executed using any suitable computing system (e.g., the controller 106, the computing device 104 of FIG. 1, the computing system 800 of FIG. 8, etc.). It may be appreciated that certain steps of the method 400 may be executed in parallel (e.g., concurrently) or sequentially, while still achieving useful results. The method 400 may be executed iteratively to generate navigator maps for each shot of a multi-shot interleaved diffusion-weighted image, as described herein.

The method 400 may include act 405, in which a reference image (e.g., the reference image 152, the reference image 205, the well-aligned structural image 302, etc.) of a subject may be obtained. The reference image may be obtained, in a non-limiting example, by capturing a structural image of a region of the subject on which a DWI scan will be performed. In a non-limiting example, the reference image may be an image of a subject that captures the same portion as a corresponding set of DWI signals (e.g., which make up a multi-shot interleaved DWI of the same subject). In some implementations, the reference image may be a zero b-value DWI scan image, and may be a complex reference image that may be well aligned with the corresponding set of DWI signals. In a non-limiting example, DWI scans in practice may include protocols with a structural imaging sequence, such as a zero b-value DWI scan. The zero b-value DWI scan provide a zero b-value image, which may be utilized as the reference image. The reference image may also be an image of the subject with different contrast (e.g., T1, T2, proton density, FLAIR), a combination of reference images, or may be an image scanned for calibration purposes. In some implementations, the reference image may be obtained (e.g., received, retrieved) from an external computing system or database.

The method 400 may include act 410, in which a multi-shot DWI image of the subject is captured. Multi-shot images divide the DWI image portion into segments, acquiring one at a time and once per shot. Such multi-shot DWI images are vulnerable to motion. In a non-limiting example, if the subject being imaged is at a different state for each shot, the composed “sufficient” portion is a mixture, and may leave artefacts in the reconstructed image. Typical patient motion may include gross motion of the body part being imaged, physiological motion, or motion of distal parts of the body (reaching into the imaging field of view, in a non-limiting example), among others. Besides motion, other potential causes of phase variation across shots of the DWI image include changes in the scanner magnetic or RF fields (e.g., eddy currents, hysteresis, movement of metal objects in or near the scanner, heating of electronics or magnetic components, etc.). The techniques described herein may be utilized to correct the phase variation across shots.

The multi-shot DWI image may be captured by any suitable MR imaging technique (e.g., via the MR system 100). In a non-limiting example, the DWI image may be captured using a low-field MR system. In some implementations, pulse sequences such as diffusion-weighted steady state free precession (DW-SSFP) sequences, which may be specifically designed for use or optimal performance in the low-field context, may be utilized to capture or acquire the DWI image. The multi-shot DWI image may also be captured using other types of MR imaging systems. Each shot of the multi-shot DWI image may include a high b-value image (e.g., a b-value that may be greater than the b-value of the reference image). A high b-value may be a range of b-values from 100 to 2000, or any b-value that may be greater than zero, in a non-limiting example. The DWI image may be acquired separately from the reference image, or during the same procedure in which the reference image is captured. In some implementations, the multi-shot DWI image may be obtained (e.g., received, retrieved) from an external computing system or database. In some implementations, the acquisition of the DWI image may utilize the same coil sensitivity profile as that used to acquire the reference image.

At a low image-resolution level, the reference image may fully (or partially beyond a predetermined threshold) overlap with the multi-shot DWI image that may be to-be-corrected using the techniques described herein. In some implementations, an image registration process may be performed to align the reference image 205 with the corresponding DWI signals 210. The image registration process may be performed between the reference image and a reconstructed version of the DWI encoded signals 210 in the image domain (e.g., without any correction, such as the DWI image shown in FIG. 6, etc.). The results of the image registration process may be a transformation (e.g., a rotation, translation) of the reference image that aligns the reference image 205 with the image corresponding to the DWI encoded signals 210. The transformation may be applied to the reference image 205 to create the well-aligned reference image, which may be provided as input to the regularized navigator map estimation solver 215.

The method 400 may include act 415, in which navigator maps for each shot of the DWI image are generated. A respective navigator map may be generated for each shot of the multi-shot DWI image acquired in act 410. The navigator maps may be utilized in phase-navigated correction of the DWI image, to correct for shot-variant motion phase in each shot of the DWI image. The navigator maps may be estimated, in a non-limiting example, by performing the processes described in connection with FIGS. 2 and 3. In some embodiments, prior to estimating the navigator maps for each shot, a shot-invariant phase difference map is estimated between the reference and the multi-shot interleaved DWI image, which may be subsequently applied to either the reference image or the multi-shot DWI such that both data have the same shot-invariant phase.

In addition to the shot-varying motion-induced phase differences, the DWI image to be corrected may contain additional phase that may be static across shots. In a non-limiting example, uncompensated DWI encoding gradient moments or eddy-current fields may generate a (spatially-varying) static phase difference with respect to the structural reference image used for estimation. The static phase map may be obtained with various different approaches (e.g., non-navigated reconstruction, gridding, machine-learning models, etc.). The static phase difference map may then be used prior to navigator map estimation to modulate the structural reference image, allowing the proposed method to focus on estimating the phase differences specifically due to temporally varying motion induced phase corruption. Similar to including a shot-invariant static phase map for improving the robustness, instead of using structural images, in some implementations the estimation may be initiated from a synthesized high b-value image obtained from, in a non-limiting example, a deep learning reconstruction method. The reference image may also be synthesized from a combination of other previously acquired images.

The shot-invariant phase difference map (sometimes referred to herein as the static phase and magnitude map) is estimated via non-navigated reconstruction of k-space data from partial or all shots of the multi-shot DWI image. Non-navigated reconstruction may be any reconstruction technique that does not involve navigated reconstruction, such as gridding or machine-learning techniques (e.g., trained convolutional neural network models, etc.), among others. Once estimated, the shot-invariant phase difference map may be applied (e.g., by element-wise multiplication or convolution, etc.) to either the reference image or the multi-shot DWI such that both data have the same shot-invariant phase. The DWI image and reference image, once having the same shot-invariant phase, may be utilized to estimate the navigator maps.

As described herein, the navigator maps may be estimated by minimizing a difference between data of the reference image convolved with the navigator map and a respective shot of the plurality of shots. This approach is described herein in connection with Formulations 2 and 3, in which regularizers and regularization terms are utilized to the phase variations between the images, which allows for calculation of navigator maps from undersampled data (e.g., captured from a low-field MR system, etc.). Any suitable regularizer may be utilized in performing the regularization process, including regularizing the phase variations using a geometric shape regularizer, a null space regularizer, or a combination of the geometric shape regularizer and the null space regularizer. The regularizer may be executed according to a set of regularization terms, as described herein, to estimate the navigator maps. Formulation 2, as described herein, may be utilized to implement an image-domain regularized minimization technique that generates the navigator maps, and Formulation 3 may be utilized to implement a frequency-domain regularized minimization technique that generates the navigator maps. In some implementations, if the reference image might be in the image domain, the reference image may be transformed into the frequency domain (e.g., utilizing a Fourier transform) prior to executing the regularized minimization techniques described herein.

In some implementations, the output of the regularized minimization process includes generation of an estimated convolutional kernel, which represents the estimated navigator map for a particular shot in the frequency domain. To generate the navigator map, the estimated convolutional kernel may be transformed into the image domain (e.g., by performing an inverse-Fourier transform. A motion phase map may be extracted as the phase component from the navigator map, and utilized to correct shot-variant phase motion in the multi-shot interleaved DWI image. A corresponding to the magnitude map may be extracted as the magnitude component from the navigator map. The magnitude component may be utilized to reject shots that include excessive motion, and the motion phase map may be utilized to correct shot-variant phase motion in each shot of the acquired DWI image.

In some implementations, the navigator maps may be estimated in a hybrid image-frequency domain. The hybrid image-frequency domain may include any intermittent domain after incomplete multi-dimensional Fourier transform. The images described herein may be multi-dimensional (e.g., 2D, 3D images). Multi-dimensional Fourier transform processes (such as those described herein) are separable processes. In a non-limiting example, for a 3D spatial domain (with Cartesian directions x, y, and z), the multi-dimensional Fourier transform may be performed by doing single-dimensional Fourier transforms along each direction sequentially (or in parallel). An incomplete multi-dimensional Fourier transform involves not completing FT along all directions (e.g., leaving at least one dimension un-transformed). To achieve a hybrid approach, the estimation process described in connection with Formulation 3 may be utilized, but utilizing an incomplete Fourier transform F as part of the Fourier transform identity.

The method 400 may include act 420, in which it may be determined whether any shots should be rejected based on the navigator maps. As described herein, the respective magnitude portion of the navigator maps estimated for each shot may be utilized to reject certain shots of the DWI image that have excessive motion. In a non-limiting example, if a magnitude map indicates a magnitude value or group of magnitude values that exceed a predetermined threshold (e.g., defined via a configuration file or user input, etc.), the respective shot may be marked as rejected. Any shots that are marked as rejected may be reacquired by executing act 410 of the method 400. Once all shots of the DWI image are determined to not indicate excessive motion, the method 400 may proceed to act 425.

The method 400 may include act 425, in which image reconstruction may be performed using the navigator maps. To do so, the navigator maps may be applied to each respective shot of the multi-shot DWI image to correct motion or system induced image phase. Applying the navigator maps may be performed by elementwise multiplication or by convolution. The navigator maps may be utilized to perform navigated image reconstruction of k-space data from all shots of the multi-shot interleaved DWI using the estimated navigator maps. Navigated reconstruction may be performed using Formulation 5 described herein, which may be solved iteratively using an iterative algorithm such as the fast iterative shrinkage-thresholding algorithm FISTA. Other suitable algorithms may also be utilized to generate the reconstruction DWI image according to Formulation 5. In some implementations, the motion phase map of the navigator map may be utilized to perform the reconstruction, rather than the entirety of the navigator map. The reconstructed DWI image may then be stored, provided for display, provided to another computing system, or subjected to further processing operations.

The techniques described herein may be utilized for any type of image encoding, and therefore may be utilized with any type of 2D, 3D, or other type of multidimensional imaging process. As described herein, a hybrid data layout may be utilized, for instance, in 3D acquisitions that are regularly sampled along the readout dimension, an inverse Fourier transform may be applied along the readout dimension. The estimation of the navigator maps, as described herein, may then be conducted on the resulting 2D k-space data. These approaches are therefore independent of both the navigator acquisition strategy and image encoding due to the use of a separate reference image. Additionally, the techniques described herein may inherently handle contrast differences between the reference image and the DWI image that may be to be corrected. The source of the structural reference image may image may be imaging data where motion sensitivity may be minimized.

These approaches described herein may further be utilized with aggressively undersampled data (e.g., a single shot out of ˜500) to estimate a navigator map. The use of a separate reference image may also be utilized for bulk motion correction. Processing efficiency may be improved by generating the navigator maps in parallel with the multi-shot DWI image acquisition process, because the estimation process does not require knowledge of the full high b-value k-space data of the full DWI image. Performing the estimation process in parallel may shorten the waiting time between the end of the data acquisition and the start of the model based high b-value image reconstruction using the motion-phase maps. Further, corrections to the image acquisition may be calculated and applied during the acquisition, including updating the image acquisition field of view or orientation to match bulk motion of the subject or determining whether to reject or reacquire DWI image shots (e.g., segments).

The estimation of the motion phase map per segment of DWI data may be improved by utilizing an image consistency metric. This metric may be a combination of consistency between segments of correction, and between segments and reference image (all of which are imaging the same portion of the subject). Note that while the various examples described herein provide techniques for a multi-shot 3D spin echo DWI sequence, the same techniques may be applied to correct any multi-shot 2D or 3D imaging sequence with a reference image.

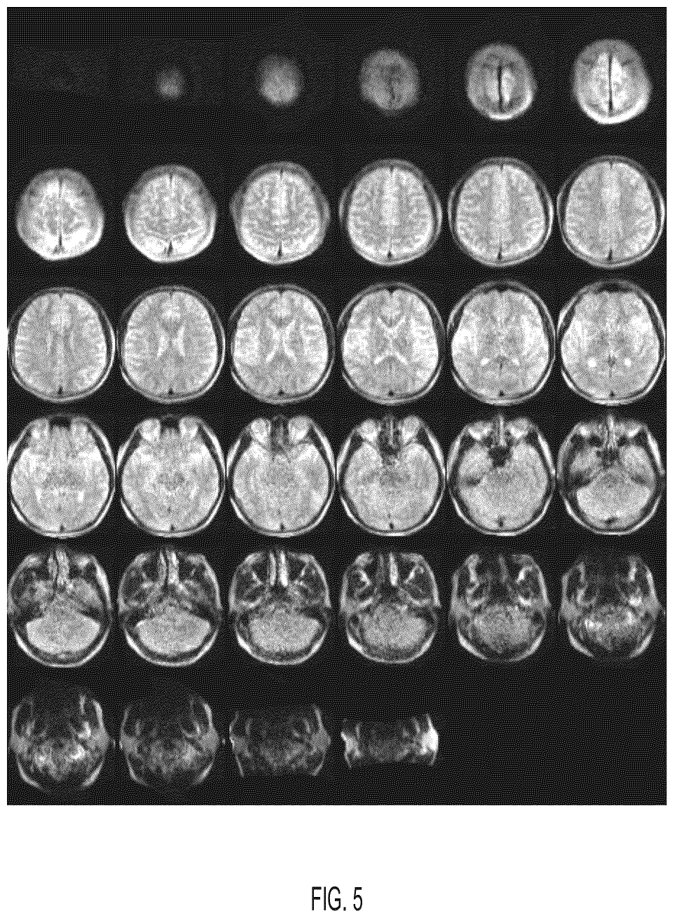

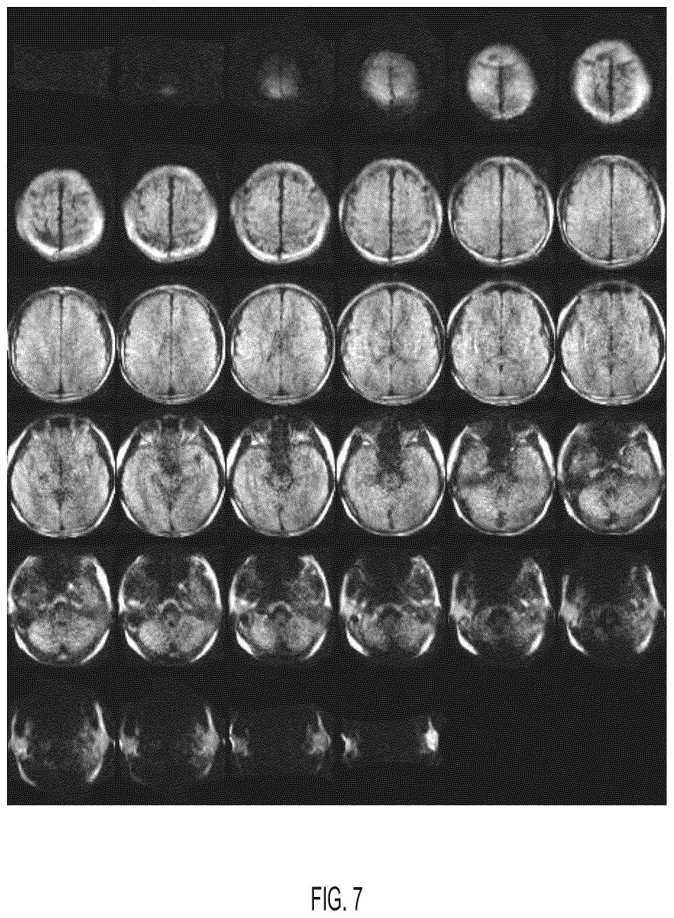

FIG. 5 shows a non-limiting example reference image of a patient, in accordance with one or more implementations. The reference image is structural image of a patient's brain. The reference image may be a three-dimensional image that may be shown here as multiple two-dimensional slices. The reference image may be utilized with the techniques described herein to correct for motion-inducted shot-varying phase differences in a DWI image. FIG. 6 shows an example DWI image of the patient of FIG. 5 without motion correction. The DWI image is a 3D image that may be shown as including the same number of slices as in FIG. 5. The DWI image is blurrier and lacks some detail compared to the reference image due to shot-varying phase differences. FIG. 7 shows an example DWI image of a patient on which image correction has been performed, in accordance with one or more implementations. The corrected DWI image of FIG. 7 shows improved clarity compared to the uncorrected DWI image. The corrected DWI image of FIG. 7 was generated using the techniques described herein.

Each of FIGS. 6 and 7 depict a 3D multi-shot spin echo DWI sequence with a b-value of 900 s/mm², with and without the phase navigator correction, respectively. The sequence includes of a spin echo DWI contrast preparation segment, followed by a spin echo train with 40 echoes. The sequence may be acquired in 518 shots. The reference image shown in FIG. 5 was acquired with the same sequence, without the DWI contrast encoding gradients, using 106 shots. Although the same type of sequence may be utilized in this example, the use of the same type of sequence for the reference image may not be necessary.

FIG. 8 illustrates a component diagram of an example computing system suitable for use in the various implementations described herein, according to an example implementation. In a non-limiting example, the computing system 800 may implement a computing device 104 or controller 106 of FIG. 1, or various other example systems and devices described in the present disclosure.

The computing system 800 includes a bus 802 or other communication component for communicating information and a processor 804 coupled to the bus 802 for processing information. The computing system 800 also includes main memory 806, such as a RAM or other dynamic storage device, coupled to the bus 802 for storing information, and instructions to be executed by the processor 804. Main memory 806 may also be used for storing position information, temporary variables, or other intermediate information during execution of instructions by the processor 804. The computing system 800 may further include a ROM 808 or other static storage device coupled to the bus 802 for storing static information and instructions for the processor 804. A storage device 810, such as a solid-state device, magnetic disk, or optical disk, is coupled to the bus 802 for persistently storing information and instructions.

The computing system 800 may be coupled via the bus 802 to a display 814, such as a liquid crystal display, or active matrix display, for displaying information to a user. An input device 812, such as a keyboard including alphanumeric and other keys, may be coupled to the bus 802 for communicating information, and command selections to the processor 804. In another implementation, the input device 812 has a touch screen display. The input device 812 may include any type of biometric sensor, or a cursor control, such as a mouse, a trackball, or cursor direction keys, for communicating direction information and command selections to the processor 804 and for controlling cursor movement on the display 814.

In some implementations, the computing system 800 may include a communications adapter 816, such as a networking adapter. Communications adapter 816 may be coupled to bus 802 and may be configured to enable communications with a computing or communications network or other computing systems. In various illustrative implementations, any type of networking configuration may be achieved using communications adapter 816, such as wired (e.g., via Ethernet), wireless (e.g., via Wi-Fi, Bluetooth), satellite (e.g., via GPS) pre-configured, ad-hoc, LAN, WAN, and the like.

According to various implementations, the processes of the illustrative implementations that are described herein may be achieved by the computing system 800 in response to the processor 804 executing an implementation of instructions contained in main memory 806. Such instructions may be read into main memory 806 from another computer-readable medium, such as the storage device 810. Execution of the implementation of instructions contained in main memory 806 causes the computing system 800 to perform the illustrative processes described herein. One or more processors in a multi-processing implementation may also be employed to execute the instructions contained in main memory 806. In alternative implementations, hard-wired circuitry may be used in place of or in combination with software instructions to implement illustrative implementations. Thus, implementations are not limited to any specific combination of hardware circuitry and software.

Various potential non-limiting embodiments and aspects of the disclosure include the following:

Embodiment AA: An image processing method for compensating for motion in multi-shot magnetic resonance (MR) images, the image processing method comprising estimating phase variations among a plurality of shots of acquired MR imaging data by: (a) acquiring a reference image of a subject; (b) calculating, for each shot of the plurality of shots, a navigator map using (i) first data of the shot, and (ii) second data of the reference image; and (c) reconstructing a multi-shot MR image of the subject by applying the navigator maps of (b) to the plurality of shots of acquired MR imaging data.

Embodiment AB: Any of the Embodiments disclosed in this Specification (e.g., any of Embodiments AA to AI), wherein the plurality of shots of acquired MR imaging data is acquired separately from the reference image.

Embodiment AC: Any of the Embodiments disclosed in this Specification (e.g., any of Embodiments AA to AI), wherein (b) comprises minimizing a regularized difference between (i) a Fourier transform of the second data of the reference image convolved with the navigator map, and (ii) a respective shot of the plurality of shots.

Embodiment AD: Any of the Embodiments disclosed in this Specification (e.g., any of Embodiments AA to AI), wherein (b) comprises minimizing a regularized difference between (i) a partial Fourier transform of the second data of the reference image convolved with the navigator map, and (ii) a respective shot of the plurality of shots.

Embodiment AE: Any of the Embodiments disclosed in this Specification (e.g., any of Embodiments AA to AI), further comprising regularizing the phase variations to allow for calculation of navigator maps from undersampled data.

Embodiment AF: Any of the Embodiments disclosed in this Specification (e.g., Embodiment AE), wherein regularizing the phase variations comprises using a geometric shape regularizer, a null space regularizer, or a combination of the geometric shape regularizer and the null space regularizer.

Embodiment AG: Any of the Embodiments disclosed in this Specification (e.g., any of Embodiments AA to AI), wherein the reference image is a diffusion-weight image (DWI) with a zero b-value, and each shot of the plurality of shots is a respective DWI image with a b-value greater than zero.

Embodiment AH: Any of the Embodiments disclosed in this Specification (e.g., any of Embodiments AA to AI), wherein the multi-shot MR image is a T1-weighted image, a T2-weighted image, a fluid-attenuated inversion recovery (FLAIR) image, a DWI image, a water separated image, a fat separated image, a fat suppressed image, a phase contrasted image, or a blood contrasted image.

Embodiment AI: Any of the Embodiments disclosed in this Specification (e.g., any of Embodiments AA to AH), wherein the navigator maps are used to select shots in the plurality of shots that should be rejected and reacquired.

Embodiment BA: A method for generating motion phase maps for multi-shot magnetic resonance image reconstruction, comprising: generating, by one or more processors, a transformation of a reference image of a subject, the reference image corresponding to a set of signals captured from a magnetic resonance (MR) scan of the subject; generating, by the one or more processors, an estimated convolutional kernel according to the set of signals and the transformation of the reference image; and generating, by the one or more processors, a motion phase map for the set of signals according to a transform of the estimated convolutional kernel.

Embodiment BB: Any of the Embodiments disclosed in this Specification, wherein the reference image of the subject is captured using a first imaging process and the set of signals are captured using a second imaging process.

Embodiment BC: Any of the Embodiments disclosed in this Specification (e.g., any of Embodiments BA to BH), wherein the set of signals correspond to a T1-weighted image, a T2-weighted image, a fluid-attenuated inversion recovery (FLAIR) image, a DWI image, a water separated image, a fat separated image, a fat suppressed image, a phase contrasted image, or a blood contrasted image.

Embodiment BD: Any of the Embodiments disclosed in this Specification (e.g., any of Embodiments BA to BH), wherein the reference image comprises a T1-weighted image, a T2-weighted image, or a fluid-attenuated inversion recovery (FLAIR) image.

Embodiment BE: Any of the Embodiments disclosed in this Specification (e.g., any of Embodiments BA to BH), further comprising generating, by the one or more processors, a navigator map comprising the motion phase map and a magnitude map according to the transformation of the estimated convolutional kernel.

Embodiment BF: Any of the Embodiments disclosed in this Specification (e.g., Embodiment BE), further comprising detecting, by the one or more processors, motion in DWI data exceeding a defined level, according to the set of signals and the navigator map.

Embodiment BG: Any of the Embodiments disclosed in this Specification (e.g., any of Embodiments BA to BH), wherein generating the estimated convolutional kernel comprises executing, by the one or more processors, a regularizer according to a set of regularization terms.

Embodiment BH: Any of the Embodiments disclosed in this Specification, further comprising generating, by the one or more processors, one or more reconstructed multi-shot MR images according to the motion phase map.

Embodiment CA: A system for generating motion phase maps for multi-shot magnetic resonance image reconstruction, comprising: one or more processors configured to: generate a transformation of a reference image of a subject, the reference image corresponding to a set of signals captured from a magnetic resonance (MR) scan of the subject; generate an estimated convolutional kernel according to the set of signals and the transformation of the reference image; and generate a motion phase map according to a transform of the estimated convolutional kernel.

Embodiment DA: An image processing method for compensating for motion in magnetic resonance (MR) images, the image processing method comprising estimating phase variations among segments of acquired imaging data by: (a) acquiring a reference image of a subject; (b) calculating, for a multi-shot MR image of the subject, a navigator map using the reference image; and (c) reconstructing the multi-shot MR image by applying the navigator maps of (b) to segments of the multi-shot MR image.

Embodiment EA: A method of magnetic resonance imaging (MRI) reconstruction with multi-shot MRI pulse sequences, comprising: (a) obtaining a reference image; (b) acquiring a multi-shot interleaved MR image that has shot-variant and shot-invariant phase modulations; (c) estimating complex-valued shot-specific navigator maps that correspond to the element-wise ratio map between (i) the multi-shot interleaved MR image with shot-varying phase modulations, and (ii) the reference image; (d) using the navigator maps to select shots that should be rejected or reacquired; (e) applying the navigator maps to correct motion or system induced image phase for the multi-shot interleaved MR image; and (f) performing navigated image reconstruction of k-space data from all shots of the multi-shot interleaved MR image using the estimated navigator maps.

Embodiment EB: Any of the Embodiments disclosed in this Specification (e.g., any of Embodiments EA to EI), wherein the reference image comprises an image with different contrast than the multi-shot interleaved MR image, a combination of reference images, or an image scanned for calibration purposes.

Embodiment EC: Any of the Embodiments disclosed in this Specification (e.g., any of Embodiments EA to EI), wherein the reference image is well-aligned with and overlaps with the multi-shot interleaved MR image.

Embodiment ED: Any of the Embodiments disclosed in this Specification (e.g., any of Embodiments EA to EI), wherein the acquisition has a same coil sensitivity profile as the reference image.

Embodiment EE: Any of the Embodiments disclosed in this Specification (e.g., any of Embodiments EA to EI), wherein a shot-invariant phase difference map is estimated between the reference and the multi-shot interleaved MR image and applied by performing operations comprising: (i) estimating the shot-invariant image phase difference map of the multi-shot interleaved MR image of (b); and (ii) applying the shot-invariant phase difference map to either the reference image or the multi-shot interleaved MR image such that both data have the same shot-invariant phase.

Embodiment EF: Any of the Embodiments disclosed in this Specification (e.g., Embodiment EE), wherein the shot-invariant phase difference map is obtained via non-navigated reconstruction of k-space data from partial or all shots of the multi-shot imaging.

Embodiment EG: Any of the Embodiments disclosed in this Specification (e.g., any of Embodiments EA to EI), wherein (c) comprises performing an image-domain regularized minimization technique that generates the navigator maps.

Embodiment EH: Any of the Embodiments disclosed in this Specification (e.g., Embodiment EG), wherein the minimization techniques are performed using k-space data or using data in a hybrid image-frequency domain.

Embodiment EI: Any of the Embodiments disclosed in this Specification (e.g., Embodiment EH), wherein the hybrid image-frequency domain is defined as any intermittent domain after incomplete multi-dimensional Fourier transform.

The implementations described herein have been described with reference to drawings. The drawings illustrate certain details of specific implementations that implement the systems, methods, and programs described herein. Describing the implementations with drawings should not be construed as imposing on the disclosure any limitations that may be present in the drawings.

It should be understood that no claim element herein is to be construed under the provisions of 35 U.S.C. § 112(f), unless the element is expressly recited using the phrase “means for.”

As used herein, the term “circuit” may include hardware structured to execute the functions described herein. In some implementations, each respective “circuit” may include machine-readable media for configuring the hardware to execute the functions described herein. The circuit may be embodied as one or more circuitry components including, but not limited to, processing circuitry, network interfaces, peripheral devices, input devices, output devices, sensors, etc. In some implementations, a circuit may take the form of one or more analog circuits, electronic circuits (e.g., integrated circuits (IC), discrete circuits, system on a chip (SOC) circuits), telecommunication circuits, hybrid circuits, and any other type of “circuit.” In this regard, the “circuit” may include any type of component for accomplishing or facilitating achievement of the operations described herein. In a non-limiting example, a circuit as described herein may include one or more transistors, logic gates (e.g., NAND, AND, NOR, OR, XOR, NOT, XNOR), resistors, multiplexers, registers, capacitors, inductors, diodes, wiring, and so on.

The “circuit” may also include one or more processors communicatively coupled to one or more memory or memory devices. In this regard, the one or more processors may execute instructions stored in the memory or may execute instructions otherwise accessible to the one or more processors. In some implementations, the one or more processors may be embodied in various ways. The one or more processors may be constructed in a manner sufficient to perform at least the operations described herein. In some implementations, the one or more processors may be shared by multiple circuits (e.g., circuit A and circuit B may comprise or otherwise share the same processor, which, in some example implementations, may execute instructions stored, or otherwise accessed, via different areas of memory). Alternatively or additionally, the one or more processors may be structured to perform or otherwise execute certain operations independent of one or more co-processors.

In other example implementations, two or more processors may be coupled via a bus to enable independent, parallel, pipelined, or multi-threaded instruction execution. Each processor may be implemented as one or more general-purpose processors, ASICs, FPGAs, GPUs, TPUs, digital signal processors (DSPs), or other suitable electronic data processing components structured to execute instructions provided by memory. The one or more processors may take the form of a single core processor, multi-core processor (e.g., a dual core processor, triple core processor, or quad core processor), microprocessor, etc. In some implementations, the one or more processors may be external to the apparatus, in a non-limiting example, the one or more processors may be a remote processor (e.g., a cloud-based processor). Alternatively or additionally, the one or more processors may be internal or local to the apparatus. In this regard, a given circuit or components thereof may be disposed locally (e.g., as part of a local server, a local computing system) or remotely (e.g., as part of a remote server such as a cloud based server). To that end, a “circuit” as described herein may include components that are distributed across one or more locations.

An exemplary system for implementing the overall system or portions of the implementations might include a general purpose computing devices in the form of computers, including a processing unit, a system memory, and a system bus that couples various system components including the system memory to the processing unit. Each memory device may include non-transient volatile storage media, non-volatile storage media, non-transitory storage media (e.g., one or more volatile or non-volatile memories), etc. In some implementations, the non-volatile media may take the form of ROM, flash memory (e.g., flash memory such as NAND, 3D NAND, NOR, 3D NOR), EEPROM, MRAM, magnetic storage, hard discs, optical discs, etc. In other implementations, the volatile storage media may take the form of RAM, TRAM, ZRAM, etc. Combinations of the above are also included within the scope of machine-readable media. In this regard, machine-executable instructions comprise, in a non-limiting example, instructions and data, which cause a general-purpose computer, special purpose computer, or special purpose processing machines to perform a certain function or group of functions. Each respective memory device may be operable to maintain or otherwise store information relating to the operations performed by one or more associated circuits, including processor instructions and related data (e.g., database components, object code components, script components), in accordance with the example implementations described herein.

It should also be noted that the term “input devices,” as described herein, may include any type of input device including, but not limited to, a keyboard, a keypad, a mouse, joystick, or other input devices performing a similar function. Comparatively, the term “output device,” as described herein, may include any type of output device including, but not limited to, a computer monitor, printer, facsimile machine, or other output devices performing a similar function.

It should be noted that although the diagrams herein may show a specific order and composition of method steps, it is understood that the order of these steps may differ from what is depicted. In a non-limiting example, two or more steps may be performed concurrently or with partial concurrence. Also, some method steps that are performed as discrete steps may be combined, steps being performed as a combined step may be separated into discrete steps, the sequence of certain processes may be reversed or otherwise varied, and the nature or number of discrete processes may be altered or varied. The order or sequence of any element or apparatus may be varied or substituted according to alternative implementations. Accordingly, all such modifications are intended to be included within the scope of the present disclosure as defined in the appended claims. Such variations will depend on the machine-readable media and hardware systems chosen and on designer choice. It is understood that all such variations are within the scope of the disclosure. Likewise, software and web implementations of the present disclosure could be accomplished with standard programming techniques with rule-based logic and other logic to accomplish the various database searching steps, correlation steps, comparison steps, and decision steps.

While this specification contains many specific implementation details, these should not be construed as limitations on the scope of any inventions or of what may be claimed, but rather as descriptions of features specific to particular implementations of the systems and methods described herein. Certain features that are described in this specification in the context of separate implementations may also be implemented in combination in a single implementation. Conversely, various features that are described in the context of a single implementation may also be implemented in multiple implementations separately or in any suitable subcombination. Moreover, although features may be described above as acting in certain combinations and even initially claimed as such, one or more features from a claimed combination may in some cases be excised from the combination, and the claimed combination may be directed to a subcombination or variation of a subcombination.

In certain circumstances, multitasking and parallel processing may be advantageous. Moreover, the separation of various system components in the implementations described above should not be understood as requiring such separation in all implementations, and it should be understood that the described program components and systems may generally be integrated together in a single software product or packaged into multiple software products.

Having now described some illustrative implementations and implementations, it is apparent that the foregoing is illustrative and not limiting, having been presented by way of example. In particular, although many of the examples presented herein involve specific combinations of method acts or system elements, those acts and those elements may be combined in other ways to accomplish the same objectives. Acts, elements, and features discussed only in connection with one implementation are not intended to be excluded from a similar role in other implementations.

The phraseology and terminology used herein is for the purpose of description and should not be regarded as limiting. The use of “including,” “comprising,” “having,” “containing,” “involving,” “characterized by,” “characterized in that,” and variations thereof herein, is meant to encompass the items listed thereafter, equivalents thereof, and additional items, as well as alternate implementations consisting of the items listed thereafter exclusively. In one implementation, the systems and methods described herein consist of one, each combination of more than one, or all of the described elements, acts, or components.

Any references to implementations or elements or acts of the systems and methods herein referred to in the singular may also embrace implementations including a plurality of these elements, and any references in plural to any implementation or element or act herein may also embrace implementations including only a single element. References in the singular or plural form are not intended to limit the presently disclosed systems or methods, their components, acts, or elements to single or plural configurations. References to any act or element being based on any information, act, or element may include implementations where the act or element is based at least in part on any information, act, or element.

Any implementation disclosed herein may be combined with any other implementation, and references to “an implementation,” “some implementations,” “an alternate implementation,” “various implementation,” “one implementation,” or the like are not necessarily mutually exclusive and are intended to indicate that a particular feature, structure, or characteristic described in connection with the implementation may be included in at least one implementation. Such terms as used herein are not necessarily all referring to the same implementation. Any implementation may be combined with any other implementation, inclusively or exclusively, in any manner consistent with the aspects and implementations disclosed herein.

References to “or” may be construed as inclusive so that any terms described using “or” may indicate any of a single, more than one, and all of the described terms.

Where technical features in the drawings, detailed description or any claim are followed by reference signs, the reference signs have been included for the sole purpose of increasing the intelligibility of the drawings, detailed description, and claims. Accordingly, neither the reference signs nor their absence have any limiting effect on the scope of any claim elements.

The foregoing description of implementations has been presented for purposes of illustration and description. It is not intended to be exhaustive or to limit the disclosure to the precise form disclosed, and modifications and variations are possible in light of the above teachings or may be acquired from this disclosure. The implementations were chosen and described in order to explain the principals of the disclosure and its practical application to enable one skilled in the art to utilize the various implementations and with various modifications as are suited to the particular use contemplated. Other substitutions, modifications, changes, and omissions may be made in the design, operating conditions and implementation of the implementations without departing from the scope of the present disclosure as expressed in the appended claims.

What is claimed is:

1. An image processing method for compensating for motion in multi-shot magnetic resonance (MR) images, the image processing method comprising estimating phase variations among a plurality of shots of acquired MR imaging data by:
(a) acquiring a reference image of a subject;
(b) calculating, for each shot of the plurality of shots, a navigator map using (i) first data of the shot, and (ii) second data of the reference image; and
(c) reconstructing a multi-shot MR image of the subject by applying the navigator maps of (b) to the plurality of shots of acquired MR imaging data.

2. The method of claim 1, wherein the plurality of shots of acquired MR imaging data is acquired separately from the reference image.

3. The method of claim 1, wherein (b) comprises minimizing a regularized difference between (i) a partial Fourier transform of the second data of the reference image convolved with the navigator map, and (ii) a respective shot of the plurality of shots.

4. The method of claim 3, further comprising regularizing the phase variations to allow for calculation of navigator maps from undersampled data.

5. The method of claim 4, wherein regularizing the phase variations comprises using a geometric shape regularizer.

6. The method of claim 1, wherein the reference image is a diffusion-weight image (DWI) with a zero b-value, and each shot of the plurality of shots is a respective DWI image with a b-value greater than zero.

7. The method of claim 1, wherein the multi-shot MR image is a T1-weighted image, a T2-weighted image, a fluid-attenuated inversion recovery (FLAIR) image, a DWI image, a water separated image, a fat separated image, a fat suppressed image, a phase contrasted image, or a blood contrasted image.

8. The method of claim 1, wherein the navigator maps are used to select shots in the plurality of shots that should be rejected and reacquired.

9. A method for generating motion phase maps for multi-shot magnetic resonance image reconstruction, comprising:
generating, by one or more processors, a transformation of a reference image of a subject, the reference image corresponding to a set of signals captured from a magnetic resonance (MR) scan of the subject;
generating, by the one or more processors, an estimated convolutional kernel according to the set of signals and the transformation of the reference image; and
generating, by the one or more processors, a motion phase map for the set of signals according to a transform of the estimated convolutional kernel.

10. The method of claim 9, wherein the reference image of the subject is captured using a first imaging process and the set of signals are captured using a second imaging process.

11. The method of claim 9, wherein the reference image comprises a T1-weighted image, a T2-weighted image, a fluid-attenuated inversion recovery (FLAIR) image, a DWI image, a water separated image, a fat separated image, a fat suppressed image, a phase contrasted image, or a blood contrasted image.

12. The method of claim 9, further comprising generating, by the one or more processors, a navigator map comprising the motion phase map and a magnitude map according to the transformation of the estimated convolutional kernel.

13. The method of claim 12, further comprising detecting, by the one or more processors, motion in DWI data exceeding a defined level, according to the set of signals and the navigator map.

14. The method of claim 9, further comprising generating, by the one or more processors, one or more reconstructed multi-shot MR images according to the motion phase map.

15. A system for generating motion phase maps for multi-shot magnetic resonance image reconstruction, comprising:
one or more processors configured to:
generate a transformation of a reference image of a subject, the reference image corresponding to a set of signals captured from a magnetic resonance (MR) scan of the subject;
generate an estimated convolutional kernel according to the set of signals and the transformation of the reference image; and
generate a motion phase map according to a transform of the estimated convolutional kernel.
